(19) United States
(12) Patent Application Publication
(10) Pub. No.: US 2025/0005353 A1
(43) Pub. Date: Jan. 2, 2025

(54) DATA PROCESSING APPARATUS AND DATA PROCESSING METHOD

(71) Applicant: TSINGHUA UNIVERSITY, Beijing (CN)

(72) Inventors: Huaqiang WU, Beijing (CN); Ruihua YU, Beijing (CN); Peng YAO, Beijing (CN); Dabin WU, Beijing (CN); Bin GAO, Beijing (CN); Hu HE, Beijing (CN); Jianshi TANG, Beijing (CN); He QIAN, Beijing (CN)

(73) Assignee: TSINGHUA UNIVERSITY, Beijing (CN)

(21) Appl. No.: 18/695,316

(22) PCT Filed: Dec. 28, 2021
(86) PCT No.: PCT/CN2021/142045

§ 371 Date: Mar. 25, 2024

(30) Foreign Application Priority Data
Sep. 26, 2021 (CN) 202111131563.0

(51) Int. Cl. G06N 3/08

(52) U.S. Cl. CPC G06N 3/08

(57) ABSTRACT

A data processing apparatus and a data processing method. The data processing apparatus includes: a bidirectional data processing module, including at least one storage and computing integration computing array; a controlling module, configured to switch a working mode of the bidirectional data processing module to an inference working mode to perform an inference computing task, and to switch the working mode of the bidirectional data processing module to a training working mode to perform a training computing task; a parameter management module, configured to set a weight parameter of the bidirectional data processing module; and an inputting and outputting module, configured to generate a computing inputting signal according to inputting data of the computing task, provide the computing inputting signal to the bidirectional data processing module, and receive a computing outputting signal from the bidirectional data processing module and generate outputting data according to the computing outputting signal.

### CROSS-REFERENCE TO RELATED APPLICATION

The present application claims the priority to Chinese Patent Application No. 202111131563.0, filed on Sep. 26, 2021, the entire disclosure of which is incorporated hereby by reference as portion of the present application.

### TECHNICAL FIELD

Embodiments of the present disclosure relate to a data processing apparatus and a data processing method.

### BACKGROUND

Currently, artificial intelligence technology based on the neural network algorithm has demonstrated powerful capabilities in many application scenarios in daily life, such as speech processing, target recognition and detection, image processing, natural language processing and the like. However, because of characteristics of the algorithm itself, the algorithm puts forward high requirements for a computing power of the hardware. Because of design characteristics of separation of storage and computing, a traditional processing device cannot effectively meet needs of an artificial intelligence application in specific scenarios in terms of power consumption and computing efficiency. At present, a large-scale neural network algorithm requires help of computing clusters with powerful computing capabilities to achieve good performance, and thus cannot be effectively deployed in scenarios with limited volume and power resources such as a mobile electronic device, an internet of things device, and an edge device.

### SUMMARY

Some embodiments of the present disclosure provide a data processing apparatus, which includes: a bidirectional data processing module, including at least one storage and computing integration computing array, configured to perform a computing task, wherein the computing task includes an inference computing task and a training computing task; a controlling module, configured to switch a working mode of the bidirectional data processing module to an inference working mode to perform the inference computing task, and to switch the working mode of the bidirectional data processing module to a training working mode to perform the training computing task; a parameter management module, configured to set a weight parameter of the bidirectional data processing module; and an inputting and outputting module, configured to respond to a controlling of the controlling module to generate a computing inputting signal according to inputting data of the computing task, provide the computing inputting signal to the bidirectional data processing module, and receive a computing outputting signal from the bidirectional data processing module and generate outputting data according to the computing outputting signal.

For example, in the data processing apparatus provided by some embodiments of the present disclosure, the computing array includes a memristor array for realizing the storage and computing integration, and the memristor array includes a plurality of memristors arranged in an array.

For example, in the data processing apparatus provided by some embodiments of the present disclosure, the parameter management module includes: a weight array writing unit, configured to write the weight parameter to the memristor array by changing a conductance value of each of the plurality of memristors using the weight parameter; and a weight array reading unit, configured to read the conductance value of each of the plurality of memristors from the memristor array to complete a reading of the weight parameter.

For example, in the data processing apparatus provided by some embodiments of the present disclosure, the inputting and outputting module includes: a first inputting sub-module, connected to a first connection end side of the bidirectional data processing module to provide an inputting signal of the first inputting data of the inference computing task; a first outputting sub-module, connected to a second connection end side of the bidirectional data processing module to receive a computing result of the inference computing task and generate a first outputting data; a second inputting sub-module, connected to the second connection end side of the bidirectional data processing module to provide an inputting signal based on the second inputting data of the training computing task; and a second outputting sub-module, connected to the first connection end side of the bidirectional data processing module to receive a computing result of the training computing task and generate a second outputting data.

For example, in the data processing apparatus provided by some embodiments of the present disclosure, the first inputting sub-module includes: a first data buffering unit; a first digital-to-analog signal converter; a first multiplexer, the first data buffering unit is configured to receive the first inputting data and provide the first inputting data to the first digital-to-analog signal converter, and the first digital-to-analog signal converter is configured to perform a digital-to-analog conversion on the first inputting data and provide a first inputting signal converted and output to the first multiplexer, the first multiplexer is configured to provide the first inputting signal to the first connection end side of the bidirectional data processing module through a selected channel, the first outputting sub-module includes: a second multiplexer; a first sampling and holding unit; a second analog-to-digital signal converter; a first shift accumulation unit; a second data buffering unit, the second multiplexer is configured to receive the first outputting signal from the second connection end side of the bidirectional data processing module, and provide the first outputting signal to the first sampling and holding unit through a selected channel, the first sampling and holding unit is configured to sample the first outputting signal and provide a sampled first outputting signal to the second analog-to-digital signal converter, and the second analog-to-digital signal converter is configured to perform an analog-to-digital conversion on the sampled first outputting signal, and provide the first outputting data converted and output to the first shift accumulation unit, the first shift accumulation unit is configured to provide the first outputting data to the second data buffering unit, and the second data buffering unit is configured to output the first outputting data, the second inputting sub-module includes: a third data buffering unit; a third digital-to-analog signal converter; a third multiplexer, the third data buffering unit is configured to receive the second inputting data and provide the second inputting data to the third digital-to-analog signal converter, and the third digital-to-analog signal converter is configured to perform a digital-to-analog conversion on the second inputting data and provide a second inputting signal converted and output to the third multiplexer, and the third multiplexer is configured to provide the second inputting signal to the second connection end side of the bidirectional data processing module through a selected channel, the second outputting sub-module includes: a fourth multiplexer; a second sampling and holding unit; a fourth analog-to-digital signal converter; a second shift accumulation unit; a fourth data buffering unit, the fourth multiplexer is configured to receive the second outputting signal from the first connection end side of the bidirectional data processing module, and provide the second outputting signal to the second sampling and holding unit through a selected channel, the second sampling and holding unit is configured to sample the second outputting signal and provide a sampled second outputting signal to the fourth analog-to-digital signal converter, the fourth analog-to-digital signal converter is configured to perform an analog-to-digital conversion on the sampled second outputting signal, and provide a second outputting data converted and output to the second shift accumulation unit, and the second shift accumulation unit is configured to provide the second outputting data to the fourth data buffering unit, and the fourth data buffering unit is configured to output the second outputting data.

For example, in the data processing apparatus provided by some embodiments of the present disclosure, the controlling module is configured to: in the inference working mode, connect the first inputting sub-module to the first connection end side of the bidirectional data processing module to provide the inputting signal of the first inputting data of the inference computing task, and connect the first outputting sub-module to the second connection end side of the bidirectional data processing module to receive the computing result of the inference computing task and generate the first outputting data; and in the training working mode, connect the second inputting sub-module to the second connection end side of the bidirectional data processing module to provide the inputting signal based on the second inputting data of the training computing task, and connect the second outputting sub-module to the first connection end side of the bidirectional data processing module to receive the computing result of the training computing task and generate the second outputting data.

For example, in the data processing apparatus provided by some embodiments of the present disclosure, the inputting and outputting module includes: a first inputting and outputting sub-module, connected to a first connection end side of the bidirectional data processing module to provide a first inputting signal based on a first inputting data of the inference computing task, and connected to the first connection end side of the bidirectional data processing module to receive a computing result of the training computing task and generate a second outputting data; a second inputting and outputting sub-module, connected to a second connection end side of the bidirectional data processing module to provide an inputting signal based on the second inputting data of the training computing task, and connected to the second connection end side of the bidirectional data processing module to receive a computing result of the inference computing task and generate the first outputting data.

For example, in the data processing apparatus provided by some embodiments of the present disclosure, the first inputting and outputting sub-module includes: a first data buffering unit; a first shift accumulation unit; a first digital-to-analog signal converter; a first analog-to-digital signal converter; a first sampling and holding unit; a first multiplexer, the first data buffering unit is configured to receive the first inputting data and provide the first inputting data to the first digital-to-analog signal converter, and the first digital-to-analog signal converter is configured to perform a digital-to-analog conversion on the first inputting data and provide a first inputting signal converted and output to the first multiplexer, the first multiplexer is configured to provide the first inputting signal to the first connection end side of the bidirectional data processing module through a selected channel, and, the first multiplexer is configured to receive a second outputting signal from the first connection end side of the bidirectional data processing module, and provide the second outputting signal to the first sampling and holding unit through a selected channel, the first sampling and holding unit is configured to sample the second outputting signal and then output a sampled second outputting signal to the first analog-to-digital signal converter, the first analog-to-digital signal converter is configured to perform an analog-to-digital conversion on the sampled second outputting signal, and provide the second outputting data converted and output to the first shift accumulation unit, the first shift accumulation unit is configured to provide the second outputting data to the first data buffering unit, the first data buffering unit is configured to output the second outputting data, the second inputting and outputting sub-module includes: a second multiplexer; a second sampling and holding unit; a second digital-to-analog signal converter; a second analog-to-digital signal converter; a second shift accumulation unit; a second data buffering unit, the second data buffering unit is configured to receive the second inputting data and provide the second inputting data to the second digital-to-analog signal converter, and the second digital-to-analog signal converter is configured to perform a digital-to-analog conversion on the second inputting data and provide a second inputting signal converted and output to the second multiplexer, and the second multiplexer is configured to provide the second inputting signal to the second connection end side of the bidirectional data processing module through a selected channel, and, the second multiplexer is configured to revive the first outputting signal from the second connection end side of the bidirectional data processing module, and provide the first outputting signal to the second sampling and holding unit through a selected channel, the second sampling and holding unit is configured to sample the first outputting signal and provide a sampled first outputting signal to the second analog-to-digital signal converter, the second analog-to-digital signal converter is configured to perform an analog-to-digital conversion on the sampled first outputting signal, and provide the first outputting data converted and output to the second shift accumulation unit, the second shift accumulation unit is configured to provide the first outputting data to the second data buffering unit, the second data buffering unit is configured to output the first outputting data.

For example, in the data processing apparatus provided by some embodiments of the present disclosure, the controlling module is configured to: in response to the inference working mode, connect the first inputting and outputting sub-module to the first connection end side of the bidirectional data processing module to provide the inputting signal of the first inputting data based on the inference computing task, and connect the second inputting and outputting sub-module to the second connection end side of the bidirectional data processing module to receive the computing result of the inference computing task and generate the first outputting data; and in the training working mode, connect the second inputting and outputting sub-module to the second connection end side of the bidirectional data processing module to provide the inputting signal of the second inputting data based on the training computing task, and connect the first inputting and outputting sub-module to the first connection end side of the bidirectional data processing module to receive the computing result of the training computing task and generate the second outputting data.

For example, the data processing apparatus provided by some embodiments of the present disclosure further includes: a multiplexing unit selection module, configured to under a controlling of the controlling module, in response to the inference working mode, select the first data buffering unit, the first digital-to-analog signal converter, and the first multiplexer to input, and select the second multiplexer, the second sampling and holding unit, the second analog-to-digital signal converter, the second shift accumulation unit and the second data buffering unit to output; in response to the training working mode, select the second data buffering unit, the second digital-to-analog signal converter, the second multiplexer to input, and select the first multiplexer, the first sampling and holding unit, the first analog-to-digital signal converter, the first shift accumulation unit and the first data buffering unit to output.

For example, the data processing apparatus provided by some embodiments of the present disclosure further includes: a processing element interface module, configured to communicate with an external device outside the data processing apparatus.

For example, the data processing apparatus provided by some embodiments of the present disclosure further includes: a functional function unit, configured to provide a non-linear arithmetic operation to the outputting data.

Some embodiments of the present disclosure provide a data processing method, for any one of the abovementioned data processing apparatus, including: obtaining a current working mode and controlling the bidirectional data processing module by the controlling module; in response to the working mode being the inference working mode, the bidirectional data processing module using an inference weight parameter used to perform the inference computing task to execute the inference computing task; in response to the working mode being the training working mode, the bidirectional data processing module using a training weight parameter used to perform the training computing task to execute the training computing task.

For example, in the data processing method provided by some embodiments of the present disclosure, the bidirectional data processing module performing the inference computing task including: receiving the first inputting data and generating a first computing inputting signal from the first inputting data; performing a storage and computing integration operation on the first computing inputting signal, and outputting a first computing outputting signal; generating the first outputting data according to the first computing outputting signal; and the bidirectional data processing module performing the training computing task including: receiving the second inputting data and generating a second computing inputting signal from the second inputting data; performing a storage and computing integration operation on the second computing inputting signal, and outputting a second computing outputting signal; and generating the second outputting data based on the second computing outputting signal.

### BRIEF DESCRIPTION OF DRAWINGS

In order to more clearly explain the technical scheme of the embodiments of the present disclosure, the attached drawings of the embodiments will be briefly introduced below. Obviously, the attached drawings in the following description only relate to some embodiments of the present disclosure, and are not limited to the present disclosure.

FIG. 1A is a schematic diagram of matrix-vector multiplication;

FIG. 1B is a schematic diagram of a memristor array used to perform matrix-vector multiplication;

FIG. 2 is a schematic diagram of a data processing apparatus that deploys a neural network algorithm for inference computing;

FIG. 3 is a flow chart of a data processing method for performing inference computing by the data processing apparatus illustrated in FIG. 2;

FIG. 4 is a schematic diagram of a data processing apparatus provided by at least one embodiment of the present disclosure;

FIG. 5 is a flow chart of a data processing method provided by at least one embodiment of the present disclosure;

FIG. 6 is a schematic diagram of another data processing apparatus provided by at least one embodiment of the present disclosure;

FIG. 7 is a flow chart of another data processing method provided by at least one embodiment of the present disclosure;

FIG. 8 is a flow chart of another data processing method provided by at least one embodiment of the present disclosure;

FIG. 9 is a schematic diagram of a data scheduling process of a plurality of data processing apparatuses;

FIG. 10 is a schematic diagram of a data processing system provided by at least one embodiment of the present disclosure;

FIG. 11 is a schematic diagram of data flow of the data processing system illustrated in FIG. 10 performing an inference computing task;

FIG. 12 is a schematic diagram of data flow of the data processing system illustrated in FIG. 10 performing a training computing task; and

FIG. 13 is a schematic diagram of data flow of the data processing system illustrated in FIG. 10 performing a layer-by-layer training computing task.

### DETAILED DESCRIPTION

In order to make the purpose, technical scheme and advantages of the embodiment of the disclosure more clear, the technical scheme of the embodiment of the disclosure will be described clearly and completely with the attached drawings. Obviously, the described embodiment is a part of the embodiment of the present disclosure, not the whole embodiment. Based on the described embodiments of the present disclosure, all other embodiments obtained by ordinary people in the field without creative labor belong to the scope of protection of the present disclosure.

Unless otherwise defined, technical terms or scientific terms used in this disclosure shall have their ordinary meanings as understood by people with ordinary skills in the field to which this disclosure belongs. The terms “first”, “second” and the like used in this disclosure do not indicate any order, quantity or importance, but are only used to distinguish different components. Similarly, similar words such as “a”, “an” or “the” do not indicate a quantity limit, but indicate the existence of at least one. Similar words such as “including” or “containing” mean that the elements or objects appearing before the word cover the elements or objects listed after the word and their equivalents, without excluding other elements or objects. Similar words such as “connected” or “connected” are not limited to physical or mechanical connection, but can include electrical connection, whether direct or indirect. “Up”, “Down”, “Left” and “Right” are only used to indicate the relative positional relationship. When the absolute position of the described object changes, the relative positional relationship may also change accordingly.

The present disclosure is described below through several specific embodiments. In order to keep the following description of the embodiments of the present disclosure clear and concise, detailed descriptions of well-known functions and components may be omitted. When any part (element) of the embodiments of the present disclosure appears in more than one drawing, the part (element) is represented by the same or similar reference number in each drawing.

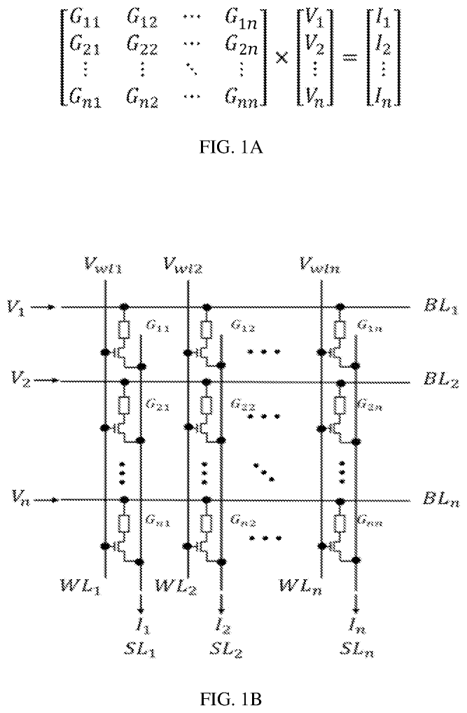

Currently, core computing steps of most neural network algorithms include a large number of matrix-vector multiplications. FIG. 1A is a schematic diagram of matrix-vector multiplication. As illustrated in FIG. 1A, a matrix G is multiplied by a column vector V to obtain a column vector I, each element I1, I2, . . . , In of the column vector I is obtained by a vector inner product multiplication of a corresponding row element of the matrix G and the column vector V. Taking that the first row of the matrix G is multiplied by the column vector V to obtain the first element I1 of the column vector as an example, n products obtained by multiplying each element of n elements G11, G12, . . . , Gln in the first row of the matrix G with each of n elements V1, V2, . . . , Vn of the column vector V are added together, so that the first element I1 corresponding to the column vector I can be obtained. A computing method of each element of the other elements I2, . . . , In of the column vector/is followed by the computing method of the element I1.

A crossbar array based on a non-volatile memory device such as a memristor array can complete a matrix-vector multiplication operation very efficiently. FIG. 1B is a schematic diagram of a memristor array used to perform matrix-vector multiplication. As illustrated in FIG. 1B, the memristor array includes n bit lines (BL) BL1, BL2, . . . , BLn and n word lines (WL) WL1, WL2, . . . , WLn which are crossed but insulated from each other, and n source lines (SL) SL1, SL2, . . . , SLn. For example, an intersection of a word line and a bit line intersects with a source line, and a memristor and a transistor are provided at the intersection, one end of the memristor is connected to the bit line, and the other end of the memristor is connected to a drain electrode of the transistor, a gate electrode of the transistor is connected to the word line, and the source electrode of the transistor is connected to the source line. A conductance value of each memristor of the memristor array is set to a value of each element G11˜Gnn of the matrix G in FIG. 1A; a value of each element V1, V2, . . . , Vn of the column vector V in FIG. 1A is mapped to a voltage value, and is applied to each bit line BL1, BL2, . . . , BLn of the memristor array; after each bit line WL1, WL2, . . . , WLn is applied column by column a turn-on voltage Vwl1, Vwl2, . . . , Vwln corresponding to each transistor in the column, according to Ohm's law and Kirchhoff's current law, an outputting current value of each of the source lines SL1, SL2, . . . , SLn is a value of each of the corresponding elements I1, I2, . . . , In of the column vector I. For example, the voltage values V1, V2, . . . , Vn applied on the n bit lines BL1, BL2, . . . , BLn are multiplied by the corresponding conductance values G11, G12, . . . , Gl of each memristor respectively, and products obtained are then accumulated to obtain the outputting current value of the source line SL1, which is the value of elements I1 of the column vector I. Therefore, by measuring the outputting current values of all columns, a result of the matrix vector multiplication illustrated in FIG. 1A can be obtained.

The storage and computing integration computing device based on the non-volatile memory array such as a memristor array has a characteristic of integrating storage and computing, compared with the traditional processor computing device, the storage and computing integration computing device has a high computing efficiency and low power consumption. Therefore, the storage and computing integration computing device can provide hardware support for deploying neural network algorithms in a wider range of scenarios.

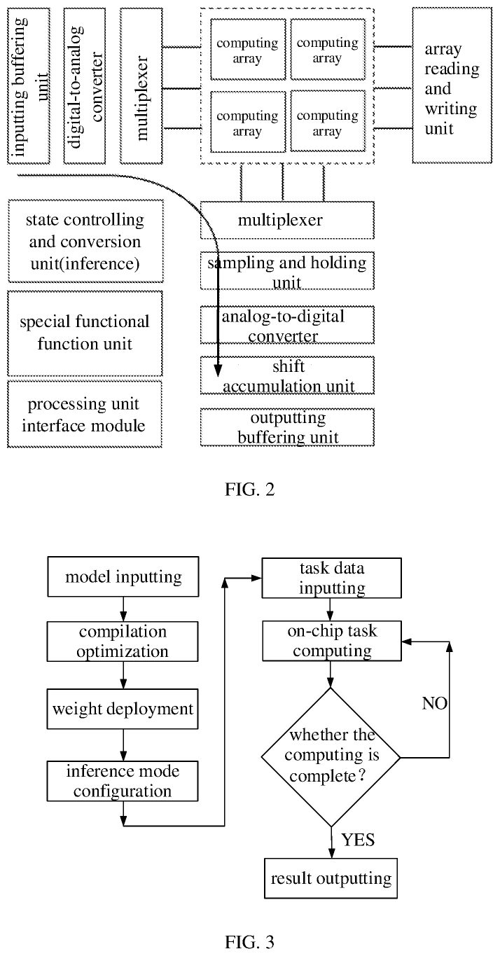

FIG. 2 is a schematic diagram of a data processing apparatus that deploys a neural network algorithm for inference computing. As illustrated in FIG. 2, the data processing apparatus (or processing element (PE)) includes an inputting module, an outputting module, a computing unit, an array reading and writing unit, a state controlling and conversion unit, a special functional function unit and a processing element interface module, these units and modules may be implemented by circuits, such as a digital circuit. Among them, the inputting module includes an inputting buffering unit, a digital-to-analog converter and a multiplexer; the outputting module includes a multiplexer, a sampling and holding unit, an analog-to-digital converter, a shift accumulation unit and an outputting buffering unit; the computing unit can include a plurality of computing arrays, each computing array is based on a memristor array. Under a controlling of the state controlling and conversion unit, the inputting module buffers and converts inputting data received, and then inputs it to the computing unit through a bit line end according to a selected channel of the multiplexer for a linear computing processing, a result processed by the computing unit is output through a source line end and then superimposed on a computing result of a non-linear operation required by the neural network algorithm, after being output through the multiplexer, it then undergoes sampling and holding and analog-to-digital conversion, and is shifted, accumulated and buffered and finally a result of an interface computing is output. A non-linear operation (such as a linear rectification operation), a non-linear activation function operation and the like are provided by a functional function unit (such as the special functional function unit). The processing element interface module is used to communicate with external devices outside the data processing apparatus, such as an external storage device, a main controlling unit, and other data processing apparatuses, for example, to transfer data, an instruction and the like, for collaborative work between apparatuses.

FIG. 3 is a flow chart of a data processing method for performing inference computing by the data processing apparatus illustrated in FIG. 2. As illustrated in FIG. 3, during the inference computing process, the data processing apparatus firstly deploys an inference model, and a deployment process includes model inputting, compilation optimization, weight deployment and inference mode configuration. After the neural network model algorithm is determined, each computing unit in the neural network model algorithm can be optimized using techniques such as model compilation to obtain an optimized weight deployment plan in the data processing apparatus. For example, after inputting structure data of the neural network model, the structure data such as weight data is compiled into a voltage signal that can be written into the memristor array, and the voltage signal is written into the memristor array to change the conductance value of each memristor of the memristor array, thereby completing the weight deployment. The data processing apparatus further configures the inputting module and the outputting module according to the model structure data input, as well as the special functional function module for realizing the non-linear operation, and the processing element interface module for communicating with the outside. After the data processing apparatus completes the deployment and configuration of the inference model, it will enter a forward inference working mode, for example, it will start to receive external task data and input the task data, according to existing configuration information, the computing unit of the data processing apparatus will start to perform a computing task to perform an on-chip task computing, until all computing tasks are completed, the data processing apparatus outputs the results to the outside, and the forward inference process is completed.

The data processing apparatus does not need to transmit data with the main controlling unit in the above process, in the case where a plurality of data processing apparatuses work together in parallel, they can transmit data through their respective processing element interface modules for data synchronization.

However, the above-mentioned data processing apparatus is oriented to an inference application of the neural network algorithm and cannot provide hardware support for a model training of the neural network algorithm. However, in order to achieve a high efficiency, current model training solutions on processor chips based on the memristor array often adopt deeply customized designs, which makes the hardware lack a certain degree of flexibility and cannot meet requirements of various neural network algorithms for inference and training.

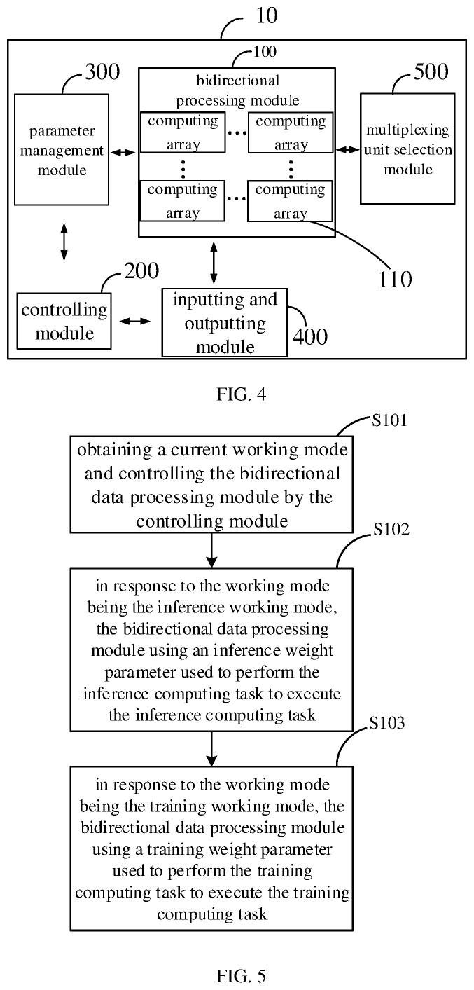

A training method of the neural network algorithm mainly uses a back propagation algorithm (BP). The back propagation algorithm is similar to updating a weight matrix of each layer of the neural network algorithm layer by layer in an opposite direction of a forward propagation algorithm of inference computing, an updated value of the weight matrix is calculated from an error value of each layer. The error value of each layer is obtained by multiplying a transpose of the weight matrix of the subsequent layer adjacent to this layer and an error value of the subsequent layer. Therefore, under a condition of obtaining an error value of the last layer of a neural network algorithm and a weight matrix of the last layer, an updating value of the weight matrix of the last layer can be calculated, and at the same time, an error value of the penultimate layer can be calculated based on the back propagation algorithm, thereby an updating value of the weight matrix of the penultimate layer can be calculated, and by analogy, until all layers of the neural network algorithm are backward updated. Therefore, at least one embodiment of the present disclosure provides a data processing apparatus that can support neural network inference and training at the same time, as illustrated in FIG. 4, the data processing apparatus includes a bidirectional processing module 100, a controlling module 200, a parameter management module 300, and an inputting and outputting module 400.

The bidirectional data processing module 100 includes one or more storage and computing integration computing arrays 110, therefore, the bidirectional data processing module 100 may include a multi-channel inputting end and a multi-channel outputting end. The bidirectional data processing module 100 is configured to perform a computing task, which include an inference computing task and a training computing task. The controlling module 200 is used to switch a working mode of the bidirectional data processing module to an inference working mode to perform the inference computing task, and to switch the working mode of the bidirectional data processing module to a training working mode to perform the training computing task. For example, the controlling module 200 may be implemented as hardware or firmware such as a CPU, SoC, FPGA, ASIC, or any combination of hardware or firmware and software. The parameter management module 300 is configured to set a weight parameter of the bidirectional data processing module. Under a controlling of the controlling module 200, the inputting and outputting module 400 generates a computing inputting signal according to inputting data of the computing task, provides the computing inputting signal to the bidirectional data processing module, and receives a computing outputting signal from the bidirectional data processing module and generates outputting data according to the computing outputting signal.

For example, the computing array 110 of the bidirectional processing module 100 may include a memristor array. The memristor array is configured to achieve the storage and computing integration. The memristor array may include a plurality of memristors arranged in an array, each memristor array may adopt a structure illustrated in FIG. 1B or other structures capable of performing matrix multiplication computing, for example, each of the memristor units that make up the memristor array does not include a switching circuit, or the memristor unit includes 2T2R (that is, two switching elements and two memristor units).

For example, the parameter management module 300 includes a weight array writing unit and a weight array reading unit. The weight array writing unit can change the conductance value of each memristor in the plurality of memristors by using the weight parameter so as to write the weight parameter into the memristor array. Correspondingly, the weight array reading unit can read the current conductance value of each memristor in the plurality of memristors from the memristor array in order to complete a reading of the current actual weight parameters, for example, the actual weight parameters are compared with presetting weight parameters to determine whether the weight parameters need to be reset again.

For example, in one example, in order to be able to perform tasks in both directions of the inference computing task and the training computing task of the neural network algorithm, the data processing apparatus can be provided with two sets of inputting modules and two sets of outputting modules, where one set of inputting module and one set of outputting module are configured to process the data inputting and data outputting of the inference computing task of the neural network algorithm, and another set of inputting module and another set of outputting module are configured to process the data inputting and data outputting of the training computing task of the neural network algorithm. In this case, the inputting and outputting module include an inference computing inputting module, an inference computing outputting module, a training computing inputting module, and a training computing outputting module. For example, the inference computing inputting module is equivalent to a first inputting sub-module of the present disclosure, the inference computing outputting module is equivalent to a first outputting sub-module of the present disclosure, the training computing inputting module is equivalent to a second inputting sub-module of the present disclosure, and the training computing outputting module is equivalent to a second outputting sub-module of the present disclosure.

For example, the inference computing inputting module can be connected to an inference computing inputting end of the bidirectional data processing module 100 and provide an inference inputting signal for the inference computing task, the inference inputting signal can be a simulation signal obtained by processing the inference inputting data through the inference computing inputting module, for example, in a form of a voltage signal applied to the bit line end of the memristor array. The inference computing outputting module can be connected to an inference computing outputting end of the bidirectional data processing module 100 to receive a computing result of the inference computing task, and the computing result is output from the source line end of the memristor array in the form of a current signal, the inference computing outputting module converts the computing result into inference outputting data and outputs it.

The training computing inputting module can be connected to a training computing inputting end of the bidirectional data processing module 100 and provide a training computing inputting signal based on the training computing task, the training computing inputting signal can be a simulation signal obtained by processing the training computing inputting data through the training computing inputting module, for example in a form of a voltage signal applied to the source line end of the memristor array. The training computing outputting module can be connected to the training computing outputting end of the bidirectional data processing module 100 to receive a computing result of the training computing task, and the computing result is output from the bit line end of the memristor array in a form of a current signal, and the data processing module 100 converts the computing result into training computing outputting data and outputs it.

For example, the inference computing inputting end of the bidirectional data processing module 100 corresponds to a first connection end side of the bidirectional data processing module of the present disclosure; the training computing inputting end of the bidirectional data processing module 100 corresponds to a second connection end side of the bidirectional data processing module of the present disclosure; the inference inputting data corresponds to the first inputting data of the present disclosure; the inference outputting data corresponds to the first outputting data of the present disclosure; the training inputting data corresponds to the second inputting data of the present disclosure; the training outputting data corresponds to the second outputting data of the present disclosure.

For example, in another example, the inference computing inputting module is functionally the same as the training computing inputting module, and can use a same type of inputting module. Either inputting module of the inference computing inputting module or the training computing inputting module may include an inputting data buffering unit (buffer), a digital-to-analog signal converter (DAC), and an inputting multiplexer (MUX). For example, in one example, the inputting data buffering unit corresponds to a first data buffering unit of the present disclosure, and in another example, corresponds to a third data buffering unit of the present disclosure; in one example, the digital-to-analog signal converter corresponds to a first digital-to-analog signal converter of the present disclosure, in another example, corresponds to a third digital-to-analog signal converter of the present disclosure; in one example, the inputting multiplexer corresponds to a first multiplexer of the present disclosure, in another example, corresponds to a third multiplexer of the present disclosure. Among them, the inputting data buffering unit can be implemented by various caches, memories and the like. The inputting data buffering unit is configured to receive inputting data, for example, the inputting data may be inference computing inputting data or training computing inputting data. After that, the inputting data buffering unit provides the inputting data to the inputting digital-to-analog signal converter, the digital-to-analog signal converter converts the inputting data from a digital signal to an analog signal, and provides an analog inputting signal converted and output to the inputting multiplexer. The inputting multiplexer may provide the analog inputting signal to the inference computing inputting end (for example, a bit line end) or a training computing inputting end (for example, a source line end) of the bidirectional data processing module 100 by a selector switch (not illustrated) through a channel selected by the multiplexer. The inference computing inputting end or the training computing inputting end of the bidirectional data processing module 100 corresponds to a plurality of computing units 110, so both have a plurality of channels.

In another example, similarly, for example, the inference computing outputting module and the training computing outputting module are further functionally the same, and can use the same type of outputting module. Either outputting module of the inference computing outputting module or the training computing outputting module can include an outputting multiplexer (MUX), a sampling and holding unit, an analog-to-digital signal converter (ADC), a shift accumulation unit, and an outputting data buffering unit and the like. For example, in one example, the outputting multiplexer corresponds to a second multiplexer of the present disclosure, and in another example, corresponds to a fourth multiplexer of the present disclosure; in one example, the sampling and holding unit corresponds to a first sampling and holding unit of the present disclosure, and in another example, corresponds to a second sampling and holding unit of the present disclosure; in one example, the analog-to-digital signal converter corresponds to a second sampling and holding unit of the present disclosure, in another example, corresponds to a fourth analog-to-digital signal converter of the present disclosure; in one example, the shift accumulation unit corresponds to a first shift accumulation unit of the present disclosure, and in another example, corresponds to a second shift accumulation unit of the present disclosure; in one example, the outputting data buffering unit corresponds to a second data buffering unit of the present disclosure, in another example, corresponds to a fourth data buffering unit of the present disclosure. By another selector switch (not illustrated), the outputting multiplexer can receive a plurality of outputting signals from the inference computing outputting end or the training computing outputting end of the bidirectional data processing module 100 through a selected channel, such as an inference computing outputting signal or a training computing outputting signal. After that, the outputting multiplexer can provide the outputting signal to the sampling and holding unit. The sampling and holding unit can be implemented by various samplers and voltage holders, and is configured to sample the outputting signal and then provide a sampled outputting signal to the analog-to-digital signal converter. The analog-to-digital signal converter is configured to convert the sampled analog outputting signal from an analog signal to a digital signal, and provide a digital outputting data converted and output to the shift accumulation unit. The shift accumulation unit can be implemented by a shift register and is configured to superimpose the outputting data and provide it to the outputting data buffering unit. The outputting data buffering unit can be implemented using the inputting data buffering unit for matching a data rate of the outputting data to an external data rate. In this example, the above two selector switch are controlled by the controlling unit, so that the entire data processing apparatus can be switched between the inference working mode and the training working mode. Furthermore, in this example, the number of the inputting signals and the number of the outputting signals of the computing array are the same.

For example, in the case where the data processing apparatus is provided with two sets of inputting modules and two sets of outputting modules, the controlling module 200 can be configured to perform the following operations. In the inference working mode, the controlling module 200 connects the inference computing inputting module to the inference computing inputting end of the bidirectional data processing module 100 to provide an inference computing inputting signal for the inference computing task, and the inference computing inputting signal can be obtained through a conversion of the inference computing inputting data by the inputting and outputting module 400. The inference computing outputting module is connected to the inference computing outputting end of the bidirectional data processing module 100 to receive the computing result of the inference computing task and generate the inference computing outputting data. In the training working mode, the controlling module 200 connects the training computing inputting module with the training computing inputting end of the bidirectional data processing module 100 to provide a training computing inputting signal based on the training computing task, the training computing inputting signal can be obtained by a conversion of the training computing inputting data by the inputting and outputting module 400. The training computing outputting module is connected to the training computing outputting end of the bidirectional data processing module 100 to receive the computing result of the training computing task and generate training computing outputting data.

For example, in another example, the data processing apparatus can further integrate the inputting module and the outputting module at the bit line end of the bidirectional data processing module 100 into a multiplexed inputting and outputting sub-module, and integrate the inputting module and the outputting module at the source line end of the bidirectional data processing module 100 into another multiplexed inputting and outputting sub-module. Therefore, the two inputting and outputting sub-modules are the same, and one of the inputting and outputting sub-modules can be connected to the bit line end of the bidirectional data processing module 100 to provide an inference computing inputting signal based on an inference computing task, and the inference computing inputting signal can be obtained by a conversion of inference computing inputting data by the inputting and outputting module 400; at the same time, the inputting and outputting sub-module receives a computing result of the training computing task and generates training computing outputting data. Another inputting and outputting sub-module can be connected to the source line end of the bidirectional data processing module 100 to provide a training computing inputting signal based on a training computing task, the training computing inputting signal can be obtained by a conversion of training computing inputting data by the inputting and outputting module 400; at the same time, the inputting and outputting sub-module receives a computing result of the inference computing task and generates inference computing outputting data.

For example, each of the inputting and outputting sub-modules may include a data buffering unit, a shift accumulation unit, a digital-to-analog signal converter, an analog-to-digital signal converter, a sampling and holding unit, and a multiplexer. For example, in one example, the data buffering unit corresponds to a first data buffering unit of the present disclosure, and in another example, corresponds to a second data buffering unit of the present disclosure; in one example, the shift accumulation unit corresponds to a first shift accumulation unit of the present disclosure, in another example, corresponds to a second shift accumulation unit of the present disclosure; in one example, the digital-to-analog signal converter corresponds to a first digital-to-analog signal converter of the present disclosure, in another example, corresponds to a second digital-to-analog signal converter of the present disclosure; in one example, the analog-to-digital signal converter corresponds to the first analog-to-digital signal converter of the present disclosure, and in another example, corresponds to a second analog-to-digital signal converter of the present disclosure; in one example, the sampling and holding unit corresponds to a first sampling and holding unit of the present disclosure, and in another example, corresponds to a second sampling and holding unit of the present disclosure; in one example, the multiplexer corresponds to a first multiplexer of the present disclosure, and in another example, corresponds to a second multiplexer of the present disclosure. In addition to the multiplexed data buffering unit and multiplexer, the remaining shift accumulation unit, the digital-to-analog signal converter, the analog-to-digital signal converter and the sampling and holding unit are implemented in the same way as in the case of the above two sets of inputting modules and two sets of outputting modules. The data buffering unit can be multiplexed, in addition to outputting the training computing outputting data, the data buffering unit can further be used to receive the inference computing inputting data and provide the inference computing inputting data to the digital-to-analog signal converter. The digital-to-analog signal converter is configured to perform a digital-to-analog conversion on the inference computing inputting data and provide the inference computing inputting signal converted and output to the multiplexer. The multiplexer may be bidirectionally multiplexed, and the multiplexer provides the inference computing inputting signal to the bit line end of the bidirectional data processing module 100 through a selected channel. At the same time, the multiplexer can further be used to receive a training computing outputting signal from the bit line end of the bidirectional data processing module 100, and the multiplexer provides the training computing outputting signal to the sampling and holding unit through the selected channel. The sampling and holding unit is configured to sample the training computing outputting signal and then provide a sampled training computing outputting signal to the analog-to-digital signal converter, the analog-to-digital signal converter is configured to perform an analog-to-digital conversion on the sampled training computing outputting signal and provide training computing outputting data converted and output to the shift accumulation unit, the shift accumulation unit is configured to provide the training computing outputting data to the data buffering unit, the data buffering unit can further be configured to output the training computing outputting data.

For example, in the case where the data processing apparatus uses a multiplexed inputting and outputting sub-module, the data processing apparatus may only include two multiplexed inputting and outputting sub-modules. The controlling module 200 may be configured to perform different operations in the inference working mode and the training working mode. In the inference working mode, the controlling module 200 can connect one inputting and outputting sub-module to the bit line end of the bidirectional data processing module 100 to provide an inference computing inputting signal based on the inference computing task, and the inference computing inputting signal can be obtained by a conversion of the inference computing inputting data. At the same time, the controlling module 200 can connect another inputting and outputting sub-module to the source line end of the bidirectional data processing module 100 to receive a computing result of the inference computing task and generate inference computing outputting data. Correspondingly, in the training working mode, the controlling module 200 can connect an inputting and outputting sub-module to the source line end of the bidirectional data processing module 100 to provide a training computing inputting signal based on the training computing task, and the training computing inputting signal can be obtained by a conversion of the training computing inputting data. At the same time, the controlling module 200 can connect another inputting and outputting sub-module to the bit line end of the bidirectional data processing module 100 to receive a computing result of the training computing task and generate training computing outputting data.

For example, in the case where the data processing apparatus uses a multiplexed inputting and outputting sub-module, the data processing apparatus may further include a multiplexing unit selection module 500. Under a controlling of the controlling module 200, the multiplexing unit selection module 500 can be configured to select the data buffering unit, the digital-to-analog signal converter and the multiplexer of one of the two inputting and outputting sub-modules in the inference working mode as an inputting channel; at the same time, the multiplexer, the sampling and holding unit, the analog-to-digital signal converter, the shift accumulation unit and the data buffering unit of another inputting and outputting sub-module are correspondingly selected as an outputting channel.

After configuring the inputting channel and outputting channel of the inference working mode, in the training working mode, only a configuration of the inputting channel and the outputting channel of the inference working mode need to be reversed. For example, in the training working mode, the multiplexing unit selection module 500 will make the multiplexer, the sampling and holding unit, the analog-to-digital signal converter, and the shift accumulation unit and the data buffering unit included in the inputting and outputting sub-module as the inputting channel in the inference working mode as the outputting channel; at the same time, correspondingly, the data buffering unit, the digital-to-analog signal converter and the multiplexer included in the inputting and outputting sub-module as the outputting channel in the inference working mode are made as the inputting channel.

For example, the data processing apparatus may further include a processing element interface module, and the processing element interface module is configured to communicate with an external device outside the data processing apparatus. For example, the data processing apparatus can perform data transmission with an external main controlling module, a memory, and the like through an interconnection device by the processing element interface module to expand a function of the data processing apparatus. The interconnection device can be a bus, an on-chip network, and the like.

For example, the data processing apparatus may further include a functional function unit, which is configured to provide a non-linear arithmetic operation on the data processed by the bidirectional data processing module 100 and output by the outputting module. For example, the functional function unit can perform non-linear operations such as a rectified linear operation (ReLU) and an S-curve activation function (SIGMOD) operation in the neural network algorithm.

At least one embodiment of the present disclosure provides a data processing method, which is used in the data processing apparatus of the embodiment of the present disclosure.

As illustrated in FIG. 5, the data processing method can be used in the data processing apparatus illustrated in FIG. 4, the data processing method includes:

Step S101, obtaining a current working mode and controlling the bidirectional data processing module by the controlling module;

Step S102, in the case of the working mode is the inference working mode, the bidirectional data processing module uses an inference weight parameter used to perform the inference computing task to execute the inference computing task;

Step S103, in the case of the working mode is the training working mode, the bidirectional data processing module uses a training weight parameter used to perform the training computing task to execute the training computing task.

The above three steps will be described in detail and non-limitingly in conjunction with FIG. 4 below.

For step S101, the controlling module of the data processing apparatus obtains the current working mode.

For example, the controlling module 200 of the data processing apparatus can determine the current working mode according to user's setting or a type of the inputting data, the current working mode includes the inference working mode and the training working mode, such as the inference working mode of the neural network algorithm and the training working mode of the neural network algorithm. For example, in the case where the type of the inputting data is inference computing inputting data, the controlling module 200 can determine the current working mode as the inference working mode; in the case where the type of the inputting data is training computing inputting data, the controlling module 200 can determine the current working mode as the training working mode. According to the working mode obtained, the controlling module can control the bidirectional data processing module to execute the corresponding working mode.

For step S102, in the case where the working mode is the inference working mode, the bidirectional data processing module uses the inference weight parameter used to perform the inference computing task to perform the inference computing task.

For example, in the inference working mode, the data processing apparatus can set the weight parameters for inference before performing the inference computing task, for example, deploying the weight parameters of each layer of the neural network algorithm to the plurality of computing arrays 110 of the bidirectional data processing module 100, and each computing array corresponds to a layer of the neural network algorithm. After the data processing apparatus sets the weight parameters for the inference computing task, it can prepare to receive the inference computing inputting data and use these weight parameters and the inputting data to perform the inference computing task.

For step S103, in the case where the working mode is the training working mode, the bidirectional data processing module uses the training weight parameter used to perform the training computing task to perform the training computing task.

For example, similar to the inference working mode, before the data processing apparatus performs the training computing task, if necessary, the weight parameters used for training can be set, or weight parameters previously used for other operations (such as the inference operation) can be used. After the data processing apparatus sets the weight parameters used for the training computing task, it can prepare to receive the training computing inputting data and use these weight parameters and the inputting data to perform the training computing task.

For example, in the case where the data processing apparatus performs the inference computing task, it may first receive an inference computing inputting data through the inputting and outputting module 400. The bidirectional data processing module 100 of the data processing apparatus is implemented based on a memristor array. The memristor array is configured to receive and process an analog signal, and an outputting is also an analog signal. In most cases, the inputting data received for the inference computing is a digital signal. Therefore, the inference computing inputting data received cannot be directly transmitted to the bidirectional data processing module 100 for processing, the digital inference computing inputting data needs to be converted into an analog inference computing inputting signal first. For example, a digital-to-analog signal converter may be used to convert the inference computing inputting data into the inference computing inputting signal.

After that, the data processing apparatus can use the bidirectional data processing module 100 to perform a storage and computing integration operation on the inference computing inputting signal converted, such as performing a matrix multiplication operation based on the memristor array. After completion of the execution, the bidirectional data processing module 100 outputs the inference computing outputting signal calculated to the inputting and outputting module 400 of the data processing apparatus for subsequent processing. The inference computing outputting signal may be a classification result after the inference computing of the neural network algorithm.

Finally, in order to facilitate subsequent data processing, the data processing apparatus needs to convert the analog signal output by the bidirectional data processing module 100 into a digital signal. For example, the data processing apparatus can convert the analog inference computing outputting signal into digital inference computing outputting data through the inputting and outputting module 400, and output the digital inference computing outputting data. For example, the inference computing inputting signal corresponds to the first computing inputting signal of the present disclosure; the inference computing outputting signal corresponds to the first computing inputting signal of the present disclosure.

For example, in the case where the data processing apparatus performs the training computing task, it is similar to the inference computing task. A process of the data processing apparatus receiving the training computing inputting data and generating the training computing inputting signal from the training computing inputting data is the same as that of the inference computing task, and will not be described again here.

After that, in the case where the bidirectional data processing module 100 of the data processing apparatus performs an storage and computing integration operation on the training computing inputting signal, for example, when performing a matrix multiplication operation based on the memristor array, it needs to output computing results of each layer of the neural network algorithm, and the computing result of each layer is output as a main controlling unit output outside the data processing apparatus of the training computing outputting signal through the inputting and outputting module 400, so that the main controlling unit can perform a residual computing. An external main controlling unit further calculates a weight updating value of each layer of the neural network algorithm based on a residual calculated, and transmits the weight updating value back to the data processing apparatus, the parameter management module 300 of the data processing apparatus updates the weight value of the array 110 of the bidirectional data processing module 100 based on the weight updating value. The weight value of the computing array 110 may correspond to the conductance value of the memristor array. A process of generating training computing outputting data according to the training computing outputting signal is the same as that of the inference computing task and will not be described again here. For example, the training computing inputting signal corresponds to the second computing inputting signal of the present disclosure; the training computing outputting signal corresponds to the second computing outputting signal of the present disclosure.

The data processing apparatus of at least one embodiment of the present disclosure can not only schedule data to obtain a higher inference efficiency driven by data flow, but also flexibly configure a data flow path under a scheduling of the controlling unit to meet requirements of various complex network model algorithm training. At the same time, the data processing apparatus has high energy efficiency and high computing power for inference and training capabilities. For example, the data processing apparatus of at least one embodiment of the present disclosure can complete a local training, implement incremental training or federated learning, and meet user customized application requirements while protecting user privacy. The data processing apparatus of at least one embodiment of the present disclosure can increase a stability and reliability of the storage and computing integration device based on the memristor array through an on-chip training or a layer-by-layer calibration, so that the storage and computing integration device can adaptively restore a system accuracy, and alleviate an impact of a device non-ideal characteristic, other noise and a parasitic parameter on system accuracy.

A data processing apparatus, a method for the data processing apparatus, and a data processing system including the data processing apparatus proposed by at least one embodiment of the present disclosure will be described below with reference to a specific but non-limiting example.

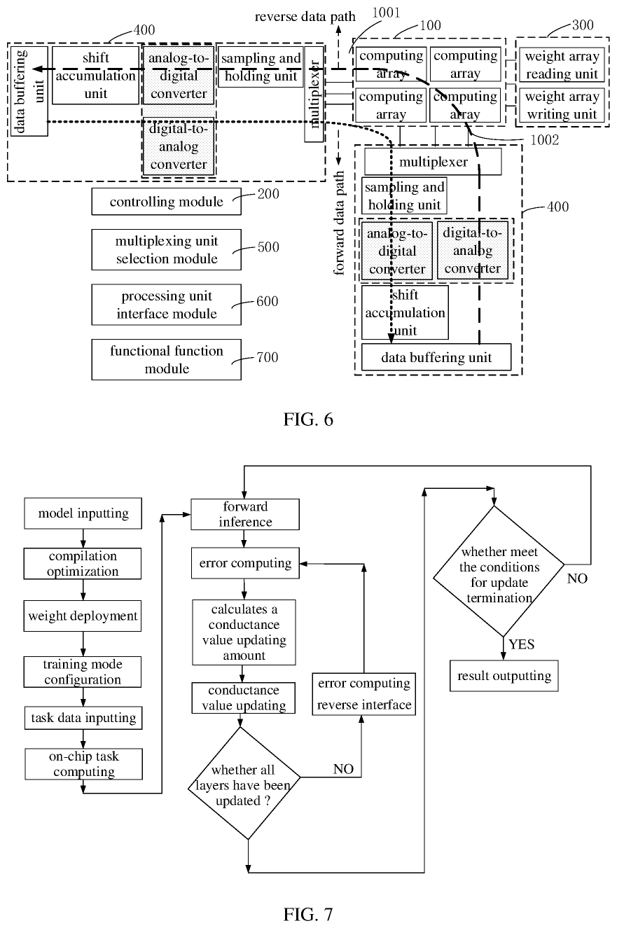

For example, FIG. 6 is a schematic diagram of another data processing apparatus provided by at least one embodiment of the present disclosure, the data processing apparatus illustrated in FIG. 6 is an implementation manner of the data processing apparatus illustrated in FIG. 4.

As illustrated in FIG. 6, the data processing apparatus includes a bidirectional data processing module 100, a controlling module 200, a parameter management module 300, two inputting and outputting modules 400, a multiplexing unit selection module 500, a processing element interface module 600 and a functional function module 700.

The bidirectional data processing module 100 has a bit line end 1001 and a source line end 1002, the bit line end 1001 can be used to receive and output data; the source line end 1002 can also be used to receive and output data, the bidirectional data processing module 100 includes one or more computing array, and each computing array may be a memristor array, the parameter management module 300 includes a weight array reading unit and a weight array writing unit, each inputting and outputting module 400 includes a data buffering unit, a shift accumulation unit, an analog-to-digital converter, a digital-to-analog converter, a sampling and holding unit, and a multiplexer. The bidirectional data processing module 100 can complete a matrix multiplication operation on the inputting data through the memristor array, and output a computing result of the matrix multiplication operation. The controlling module 200 is configured to control the data processing apparatus to perform a computing task. The parameter management module 300 converts a weight value into a writing voltage signal of the memristor array of the bidirectional data processing module 100 through the weight array writing unit, thereby changing a conductance value of each memristor unit of the memristor array to complete a writing of the weight value; or the parameter management module 300 reads the conductance value of each memristor of the memristor array of the bidirectional data processing module 100 as the weight value through the weight array reading unit.

The data processing apparatus is compatible with a forward data path and a backward data path. The forward data path may be a path for performing the inference computing task of the neural network algorithm, and the backward data path may be a path for performing the training computing task of the neural network algorithm. An inputting part of the forward data path and an outputting part of the backward data path may share a same inputting and outputting module 400, and an outputting part of the forward data path and an inputting part of the backward data path may further share a same inputting and outputting module 400. In the same inputting and outputting module 400, the data buffering unit and the multiplexer can be shared (multiplexed) for the forward data path and the backward data path. The multiplexing unit selection module 500 is configured to configure the data buffering unit and the multiplexer shared by the forward data path and the backward data path. For example, in the case where the data processing module performs a task of the forward data path, the multiplexing unit selection module 500 configures the data buffering unit and multiplexer in one of the inputting and outputting modules 400 to an inputting mode, and the inputting and outputting module 400 can be configured for the inputting of the forward data path, and the multiplexing unit selection module 500 configures the data buffering unit and the multiplexer in another inputting and outputting module 400 to an outputting mode, and the inputting and outputting module 400 can be configured for the inputting of the backward data path. On the contrary, in the case where the data processing module performs a task of the backward data path, the multiplexing unit selection module 500 only needs to configure the above process in reverse. When the data processing apparatus performs the task of the backward data path, for example, when performing the training computing task of the neural network algorithm, the processing element interface module 600 is configured to transmit the error value of the computing results of each layer in the neural network model to a main controlling unit outside the data processing apparatus to perform a weight value updating computing and transmit the weight updating value calculated back to the data processing apparatus. The functional function unit 700 is configured to provide a non-linear arithmetic function in the neural network model, for example non-linear operations such as a linear rectification operation and a non-linear activation function operation.

FIG. 7 is a flow chart of another data processing method provided by at least one embodiment of the present disclosure, and the data processing method is used in the data processing apparatus illustrated in FIG. 6.

For example, a process of the data processing apparatus performing a task of the forward data path is the same as the process of the aforementioned inference computing method, and will not be described again here. A method flow of the data processing apparatus performing the task of the backward data path is illustrated in FIG. 7. In FIG. 7, according to a back propagation algorithm (BP), the data processing apparatus first inputs training cluster data in batches (Batch), the training cluster data includes a data item and a label value (Lable), according to an inference computing method, all batches of training cluster data are subjected to inference computing on the data processing apparatus, and an outputting result of each batch of training cluster data and intermediate results of the inference computing process are obtained and recorded. The inference computing includes seven steps of model inputting, compilation optimization, weight deployment, training mode configuration, task data inputting, on-chip task computing and forward inference. In the backward data path, the training mode configuration can be to configure the data processing apparatus according to the training computing method, for example, the data buffering unit and the multiplexer of the inputting and outputting module can be configured through the multiplexing unit selection module to a data direction corresponding to the backward data path. The task data inputting can be input from the source line end of the bidirectional data processing module. Steps of the model inputting, compilation optimization, weight deployment, on-chip task computing and forward inference are the same as the corresponding steps illustrated in FIG. 3 and will not be described again here.

During the inference computing task, the result of the inference computing can be output from the bit line end of the bidirectional data processing module. After the inference computing task is completed, the data processing apparatus transmits an outputting result, an intermediate result and a label value of the inference computing to the main controlling unit outside the data processing apparatus through a processing element interface module. The main controlling unit obtains an error of the last outputting layer based on a difference between the label value and the outputting result, that is, completes an error computing, and then calculates a weight updating gradient of the last outputting layer, thereby calculating a weight updating value, and transmits the weight updating value to the data processing apparatus through the processing element interface module. The final outputting layer belongs to a neural network model used for this inference computing. The parameter management module of the data processing apparatus calculates a conductance value updating amount according to the weight updating value, converts the conductance value updating amount into a voltage value that can be written into the memristor array, and writes the voltage value into memristor array corresponding to the last outputting layer through the weight array writing unit to update the final outputting layer weight. In the same way, the other layers follow a similar approach, the weight gradient of the layer can be obtained according to the weight value of the previous layer and the error of the previous layer, so that the weight updating value of the current layer can be obtained, until all layers are updated. Finally, in the case where all the training cluster data has been trained and the weights have been updated, a verification cluster can be used for evaluation to determine whether to terminate the training, if a condition for terminating training is met, the data processing apparatus outputs the training result, otherwise, the data processing apparatus continues to input training data and perform a new round of training.

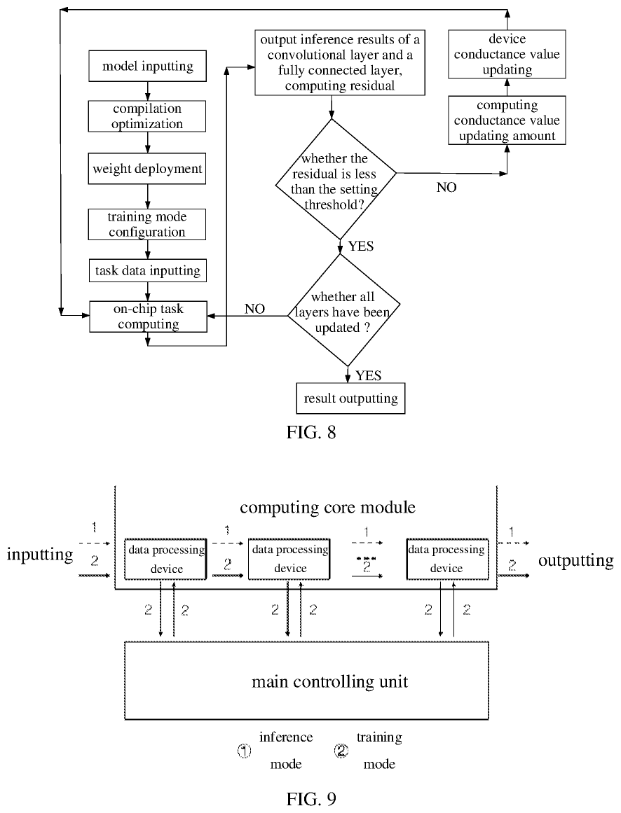

FIG. 8 is a flow chart of another data processing method provided by at least one embodiment of the present disclosure, the data processing method can be a layer-by-layer training method in which a neural network algorithm executes a backward data path, and can be used in the data processing apparatus illustrated in FIG. 6.

For example, the data processing apparatus may use a layer-by-layer neural network model training method. As illustrated in FIG. 8, the data processing apparatus can further meet a requirement of a neural network inference acceleration application and update the weight values of each layer of the neural network model in a layer-by-layer training manner, thereby adjusting the conductance value of the memristor array corresponding to each layer of the neural network model. The method flow of a layer-by-layer training is provided as follows: first, initialized weights are deployed on a hardware of the data processing apparatus, and forward inference computing is performed, where six steps of model inputting, compilation optimization, weight deployment, training mode configuration, task data inputting and on-chip task computing included in the inference computing are the same as the corresponding steps illustrated in FIG. 7, and will not be described again here. A processing interface module of the data processing apparatus will output inference results of a convolutional layer and a fully connected layer of the neural network algorithm, as well as inference results of the neural network algorithm software model with well-trained weights, to the main controlling module outside the data processing apparatus. The main controlling module compares the inference results of the convolutional layer and the fully connected layer of the neural network algorithm with the inference results of the network algorithm software model with well-trained weights, calculates a residual of each layer, and determines whether the current residual of each layer is within a presetting threshold range, in the case where the residual value is not within the threshold range, the main controlling module calculates a weight value variation according to the residual value and the outputting result of the previous layer, and output an updating amount of the weight value to the data processing apparatus. Therefore, the parameter management module of the data processing apparatus generates a memristor array conductance value writing voltage signal according to the updating amount of the weight value, and writes it into the memristor array to update the conductance value; in the case where the residual value is within the threshold range, the next layer is calibrated until all convolutional layers and fully connected layers have been calibrated, and the training results are output.

By training the data processing apparatus layer by layer, an impact of non-ideal factors on an accuracy of the final trained neural network algorithm can be resisted, the accuracy of the neural network algorithm can be greatly improved, the weight values of the neural network algorithm can be updated in a more refined manner, and the computing results of the neural network algorithm are more finely calibrated.

FIG. 9 is a schematic diagram of a data scheduling process of a plurality of data processing apparatuses. As illustrated in FIG. 9, a computing core module includes a plurality of data processing apparatuses illustrated in FIG. 6, the plurality of data processing apparatuses transmit information to each other through a processing element interface module, and the plurality of data processing apparatuses transmits information with the main controlling unit through the processing element interface module. Under a forward data path task, such as the inference working mode of the neural network algorithm, the computing core module accepts external data inputting and distributes the data inputting to each data processing apparatus. After receiving data inputting, each data processing apparatus performs the inference computing task of the forward data path according to existing configuration information until all computing tasks are completed, the computing core module outputs computing results of each data processing apparatus to the outside. In order to obtain a high execution efficiency, each data processing apparatus may not need to transmit information with the main controlling unit. In addition, information can further be transmitted between various data processing apparatuses through a bus module. Under the backward data path task, for example, in the training mode of the neural network algorithm, the data processing apparatus not only needs to perform the above-mentioned inference computing tasks, but also needs to obtain weight updating values of the convolutional layer and the fully connected layer of the neural network algorithm to update the conductance value of the memristor array, so the data flow is more complex than the inference working mode. Therefore, each data processing apparatus needs to use the main controlling unit for data scheduling, so as to calculate a magnitude of the weight value updating of the convolution layer and the fully connected layer of the neural network algorithm through the main controlling unit, and obtain the weight updating value through the processing element interface module back.

FIG. 10 is a schematic diagram of a data processing system provided by at least one embodiment of the present disclosure. The data processing system includes the data processing apparatus illustrated in FIG. 6, which can be configured to perform the inference computing task and the training computing task of the neural network algorithm.

As illustrated in FIG. 10, the data processing system includes: a routing module, a computing core module, a main controlling unit, a bus module, an interface module, a clock module and a power supply module. The routing module is configured for data inputting and data outputting between the data processing system and the outside. The data inputting includes inputting external data to the computing core module through the routing module or transmitting it to the main controlling unit through the bus module; the data outputting includes outputting data processed by the data processing system to the outside of the data processing system through the routing module. The computing core module is configured to implement matrix-vector multiplication, activation, pooling and other operations of the neural network algorithm, and receives data through the routing module or the bus module. The main controlling unit is configured for data scheduling of the training computing task, for example, the main controlling unit can transmit data with the computing core module and the routing module through the bus module, the main controlling unit can be implemented by, but is not limited to, an embedded microprocessor, such as based on RISC-V architecture or ARM architecture MCU and the like. The main controlling module can configure different interface addresses through the bus module to control and transmit data to other modules. The bus module is configured to provide data transmission protocols between modules and perform data transmission. For example, the bus module can be an AXI bus. Each module has a different bus interface address, and the data transmission of the modules can be completed by configuring the data address information of each module. The interface module is configured to expand capabilities of the data processing system, and the interface module can connect different peripherals through interfaces of various protocols. For example, the interface module may be, but is not limited to, a PCIE interface, an SPI interface and the like, to realize a function of transmitting data and instructions between the data processing system and more external devices. The clock module is configured to provide working clocks for digital circuits in each of the modules. The power module is configured to manage a working power of each of the modules.

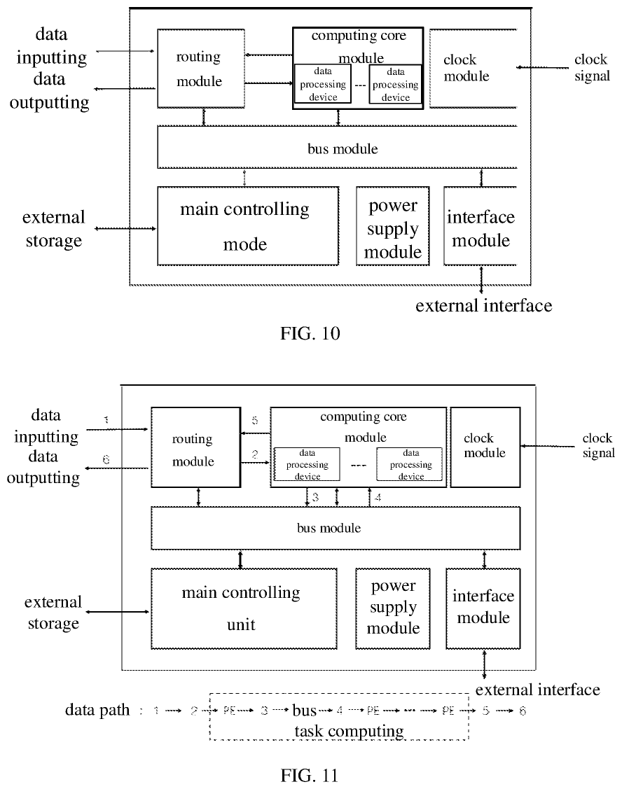

FIG. 11 is a schematic diagram of data flow of the data processing system illustrated in FIG. 10 performing an inference computing task. For example, as illustrated in FIG. 11, in the forward data path task, such as in an inference mode, the data path can be: the routing module receives inputting data from the outside, and then passes it to the computing core module for inference computing. In the case where the number of model parameters is large, the model weights will be deployed in a plurality of data processing apparatuses of the computing core module, at this time, data can be transmitted between data processing apparatuses with data dependencies through the bus module. The plurality of data processing apparatuses of the computing core module perform inference computing processing on the inputting data according to a configuration until all the inputting data are calculated. After the computing is completed, computing results will be output to the outside of the system through the routing module.

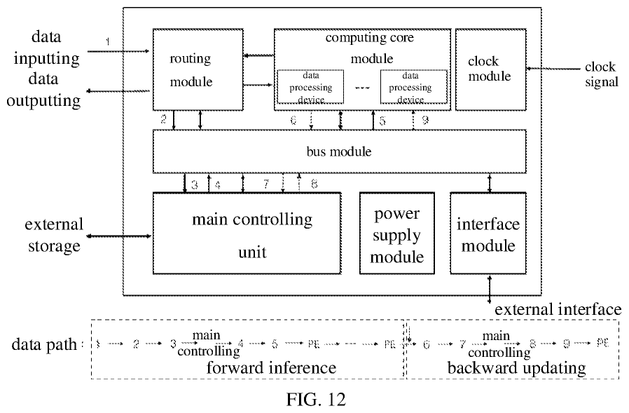

FIG. 12 is a schematic diagram of data flow of the data processing system illustrated in FIG. 10 performing a training computing task. In the backward data path task, for example, in a training mode, as illustrated in FIG. 12, the data path can be: the routing module receives inputting data from the outside, and then passes it to the main controlling unit and the computing core module through the bus module, a residual value of each layer of the neural network algorithm is calculated through forward inference computing, and a weight updating value is calculated according to the residual value of each layer and an inputting corresponding to the layer. A weight updating computing process in the forward inference computing process can be processed and implemented by the main controlling unit, in this process, the computing core module transmits data with the main controlling unit through the bus module. After the weight updating value of each layer of the neural network algorithm is obtained, the main controlling unit sends a controlling signal to configure the corresponding data processing module to update the weight. The entire training process requires backward transmission of the residuals of the outputting layer of the neural network algorithm to obtain the residual of each layer, and the execution is circular until the training updating of all layers of the neural network algorithm is completed.

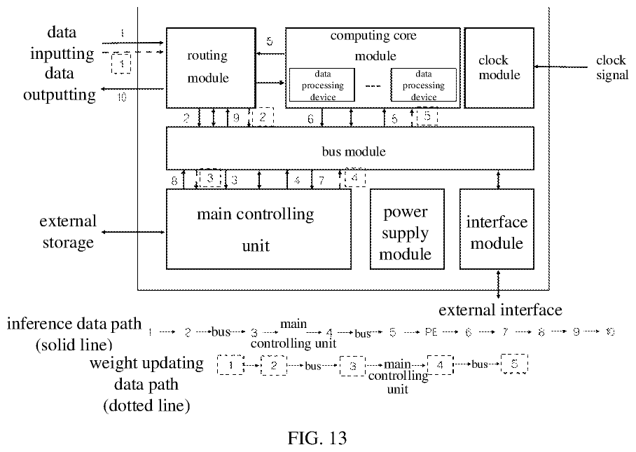

FIG. 13 is a schematic diagram of data flow of the data processing system illustrated in FIG. 10 performing a layer-by-layer training computing task. In the backward data path task, for example, in a layer-by-layer training mode, as illustrated in FIG. 13, the data path can be: the routing module receives inputting data from the outside, and then passes it to the main controlling unit through the bus module, and then the main controlling unit can transfer the data to the computing core module through the bus module to perform the training computing task, in the case where operations of the neural network algorithm convolution layer and the fully connected layer are completed, computing results will be transferred to the main controlling unit through the bus module, and the main controlling unit will transmit the computing results to the routing module through the bus module, so that the computing results are output to the outside of the data processing system through the routing module. Outside the data processing system, the computing results are compared with computing results calculated by the neural network algorithm software model to obtain a weight updating value, the weight updating value is transmitted to the interior of the data processing system through the routing module and transmitted to the main controlling unit through the bus module, then the main controlling unit transmits the weight updating value to the computing core module through the bus module, and a corresponding data processing module is configured to update the weight, this layer-by-layer training computing process will be executed until a difference between the computing results of the data processing system and the computing results of the external neural network algorithm software is within a setting threshold value. Therefore, by training the neural network algorithm layer by layer, the data processing system can update the weight value of the data processing apparatus more precisely, thereby an impact of a non-ideal factor of the data processing system on the final recognition accuracy of the neural network algorithm can be resisted more effectively.

Therefore, the data processing system can not only perform a data scheduling driven by data flow to meet the efficiency requirements of the neural network algorithm inference operation, but also realize a fine-grained scheduling of data flow under the controlling of the main controlling unit to support the inference and training computing tasks of various neural network algorithms to adapt to the requirements of various application scenarios.

For the present disclosure, the following points need to be explained:

(1) The drawings of the embodiment of this disclosure only relate to the structure related to the embodiment of this disclosure, and other structures can refer to the general design.

(2) In case of no conflict, the embodiment of the present disclosure and the features in the embodiment can be combined with each other to obtain a new embodiment.

The above is only the specific embodiment of this disclosure, but the protection scope of the present disclosure is not limited thereto, and the protection scope of this disclosure should be subject to the protection scope of the claims.

1. A data processing apparatus, comprising:
a bidirectional data processing module, comprising at least one storage and computing integration computing array, configured to perform a computing task, wherein the computing task comprises an inference computing task and a training computing task;
a controlling module, configured to switch a working mode of the bidirectional data processing module to an inference working mode to perform the inference computing task, and to switch the working mode of the bidirectional data processing module to a training working mode to perform the training computing task;
a parameter management module, configured to set a weight parameter of the bidirectional data processing module; and
an inputting and outputting module, configured to respond to a controlling of the controlling module to generate a computing inputting signal according to inputting data of the computing task, provide the computing inputting signal to the bidirectional data processing module, and receive a computing outputting signal from the bidirectional data processing module and generate outputting data according to the computing outputting signal.

2. The data processing apparatus according to claim 1, wherein the computing array comprises a memristor array for realizing the storage and computing integration, and the memristor array comprises a plurality of memristors arranged in an array.

3. The data processing apparatus according to claim 2, wherein the parameter management module comprises:
a weight array writing unit, configured to write the weight parameter to the memristor array by changing a conductance value of each of the plurality of memristors using the weight parameter; and
a weight array reading unit, configured to read the conductance value of each of the plurality of memristors from the memristor array to complete a reading of the weight parameter.

4. The data processing apparatus according to claim 1, wherein the inputting and outputting module comprises:
a first inputting sub-module, connected to a first connection end side of the bidirectional data processing module to provide an inputting signal of the first inputting data of the inference computing task;
a first outputting sub-module, connected to a second connection end side of the bidirectional data processing module to receive a computing result of the inference computing task and generate a first outputting data;
a second inputting sub-module, connected to the second connection end side of the bidirectional data processing module to provide an inputting signal based on the second inputting data of the training computing task; and
a second outputting sub-module, connected to the first connection end side of the bidirectional data processing module to receive a computing result of the training computing task and generate a second outputting data.

5. The data processing apparatus according to claim 4, wherein
the first inputting sub-module comprises:
a first data buffering unit;
a first digital-to-analog signal converter;
a first multiplexer,
wherein the first data buffering unit is configured to receive the first inputting data and provide the first inputting data to the first digital-to-analog signal converter, and the first digital-to-analog signal converter is configured to perform a digital-to-analog conversion on the first inputting data and provide a first inputting signal converted and output to the first multiplexer, the first multiplexer is configured to provide the first inputting signal to the first connection end side of the bidirectional data processing module through a selected channel,
the first outputting sub-module comprises:
a second multiplexer;
a first sampling and holding unit;
a second analog-to-digital signal converter;
a first shift accumulation unit;
a second data buffering unit,
wherein the second multiplexer is configured to receive the first outputting signal from the second connection end side of the bidirectional data processing module, and provide the first outputting signal to the first sampling and holding unit through a selected channel, the first sampling and holding unit is configured to sample the first outputting signal and provide a sampled first outputting signal to the second analog-to-digital signal converter, and the second analog-to-digital signal converter is configured to perform an analog-to-digital conversion on the sampled first outputting signal, and provide the first outputting data converted and output to the first shift accumulation unit, the first shift accumulation unit is configured to provide the first outputting data to the second data buffering unit, and the second data buffering unit is configured to output the first outputting data,
the second inputting sub-module comprises:
a third data buffering unit;
a third digital-to-analog signal converter;
a third multiplexer,
wherein the third data buffering unit is configured to receive the second inputting data and provide the second inputting data to the third digital-to-analog signal converter, and the third digital-to-analog signal converter is configured to perform a digital-to-analog conversion on the second inputting data and provide a second inputting signal converted and output to the third multiplexer, and the third multiplexer is configured to provide the second inputting signal to the second connection end side of the bidirectional data processing module through a selected channel,
the second outputting sub-module comprises:
a fourth multiplexer;
a second sampling and holding unit;
a fourth analog-to-digital signal converter;
a second shift accumulation unit;
a fourth data buffering unit,
wherein the fourth multiplexer is configured to receive the second outputting signal from the first connection end side of the bidirectional data processing module, and provide the second outputting signal to the second sampling and holding unit through a selected channel, the second sampling and holding unit is configured to sample the second outputting signal and provide a sampled second outputting signal to the fourth analog-to-digital signal converter, the fourth analog-to-digital signal converter is configured to perform an analog-to-digital conversion on the sampled second outputting signal, and provide a second outputting data converted and output to the second shift accumulation unit, and the second shift accumulation unit is configured to provide the second outputting data to the fourth data buffering unit, and the fourth data buffering unit is configured to output the second outputting data.

6. The data processing apparatus according to claim 4, wherein the controlling module is configured to:
in the inference working mode, connect the first inputting sub-module to the first connection end side of the bidirectional data processing module to provide the inputting signal of the first inputting data of the inference computing task, and connect the first outputting sub-module to the second connection end side of the bidirectional data processing module to receive the computing result of the inference computing task and generate the first outputting data; and
in the training working mode, connect the second inputting sub-module to the second connection end side of the bidirectional data processing module to provide the inputting signal based on the second inputting data of the training computing task, and connect the second outputting sub-module to the first connection end side of the bidirectional data processing module to receive the computing result of the training computing task and generate the second outputting data.

7. The data processing apparatus according to claim 1, wherein the inputting and outputting module comprises:
a first inputting and outputting sub-module, connected to a first connection end side of the bidirectional data processing module to provide a first inputting signal based on a first inputting data of the inference computing task, and connected to the first connection end side of the bidirectional data processing module to receive a computing result of the training computing task and generate a second outputting data;
a second inputting and outputting sub-module, connected to a second connection end side of the bidirectional data processing module to provide an inputting signal based on the second inputting data of the training computing task, and connected to the second connection end side of the bidirectional data processing module to receive a computing result of the inference computing task and generate the first outputting data.

8. The data processing apparatus according to claim 7, wherein
the first inputting and outputting sub-module comprises:
a first data buffering unit;
a first shift accumulation unit;
a first digital-to-analog signal converter;
a first analog-to-digital signal converter;
a first sampling and holding unit;
a first multiplexer,
wherein the first data buffering unit is configured to receive the first inputting data and provide the first inputting data to the first digital-to-analog signal converter, and the first digital-to-analog signal converter is configured to perform a digital-to-analog conversion on the first inputting data and provide a first inputting signal converted and output to the first multiplexer, the first multiplexer is configured to provide the first inputting signal to the first connection end side of the bidirectional data processing module through a selected channel, and, the first multiplexer is configured to receive a second outputting signal from the first connection end side of the bidirectional data processing module, and provide the second outputting signal to the first sampling and holding unit through a selected channel, the first sampling and holding unit is configured to sample the second outputting signal and then output a sampled second outputting signal to the first analog-to-digital signal converter, the first analog-to-digital signal converter is configured to perform an analog-to-digital conversion on the sampled second outputting signal, and provide the second outputting data converted and output to the first shift accumulation unit, the first shift accumulation unit is configured to provide the second outputting data to the first data buffering unit, the first data buffering unit is configured to output the second outputting data,
the second inputting and outputting sub-module comprises:
a second multiplexer;
a second sampling and holding unit;
a second digital-to-analog signal converter;
a second analog-to-digital signal converter;
a second shift accumulation unit;
a second data buffering unit,
wherein the second data buffering unit is configured to receive the second inputting data and provide the second inputting data to the second digital-to-analog signal converter, and the second digital-to-analog signal converter is configured to perform a digital-to-analog conversion on the second inputting data and provide a second inputting signal converted and output to the second multiplexer, and the second multiplexer is configured to provide the second inputting signal to the second connection end side of the bidirectional data processing module through a selected channel, and, the second multiplexer is configured to revive the first outputting signal from the second connection end side of the bidirectional data processing module, and provide the first outputting signal to the second sampling and holding unit through a selected channel, the second sampling and holding unit is configured to sample the first outputting signal and provide a sampled first outputting signal to the second analog-to-digital signal converter, the second analog-to-digital signal converter is configured to perform an analog-to-digital conversion on the sampled first outputting signal, and provide the first outputting data converted and output to the second shift accumulation unit, the second shift accumulation unit is configured to provide the first outputting data to the second data buffering unit, the second data buffering unit is configured to output the first outputting data.

9. The data processing apparatus according to claim 7, wherein the controlling module is configured to:
in response to the inference working mode, connect the first inputting and outputting sub-module to the first connection end side of the bidirectional data processing module to provide the inputting signal of the first inputting data based on the inference computing task, and connect the second inputting and outputting sub-module to the second connection end side of the bidirectional data processing module to receive the computing result of the inference computing task and generate the first outputting data; and
in the training working mode, connect the second inputting and outputting sub-module to the second connection end side of the bidirectional data processing module to provide the inputting signal of the second inputting data based on the training computing task, and connect the first inputting and outputting sub-module to the first connection end side of the bidirectional data processing module to receive the computing result of the training computing task and generate the second outputting data.

10. The data processing apparatus according to claim 8, further comprising:
a multiplexing unit selection module, configured to under a controlling of the controlling module,
in response to the inference working mode, select the first data buffering unit, the first digital-to-analog signal converter, and the first multiplexer to input, and select the second multiplexer, the second sampling and holding unit, the second analog-to-digital signal converter, the second shift accumulation unit and the second data buffering unit to output;
in response to the training working mode, select the second data buffering unit, the second digital-to-analog signal converter, the second multiplexer to input, and select the first multiplexer, the first sampling and holding unit, the first analog-to-digital signal converter, the first shift accumulation unit and the first data buffering unit to output.

11. The data processing apparatus according to claim 1, further comprising:
a processing element interface module, configured to communicate with an external device outside the data processing apparatus.

12. The data processing apparatus according to claim 1, further comprising:
a functional function unit, configured to provide a non-linear arithmetic operation to the outputting data.

13. A data processing method, for the data processing apparatus according to claim 1, comprising:
obtaining a current working mode and controlling the bidirectional data processing module by the controlling module;
in response to the working mode being the inference working mode, the bidirectional data processing module using an inference weight parameter used to perform the inference computing task to execute the inference computing task;
in response to the working mode being the training working mode, the bidirectional data processing module using a training weight parameter used to perform the training computing task to execute the training computing task.

14. The data processing method according to claim 13, wherein
the bidirectional data processing module performing the inference computing task comprising:
receiving the first inputting data and generating a first computing inputting signal from the first inputting data;
performing a storage and computing integration operation on the first computing inputting signal, and outputting a first computing outputting signal;
generating the first outputting data according to the first computing outputting signal; and
the bidirectional data processing module performing the training computing task comprising:
receiving the second inputting data and generating a second computing inputting signal from the second inputting data;
performing a storage and computing integration operation on the second computing inputting signal, and outputting a second computing outputting signal; and
generating the second outputting data based on the second computing outputting signal.

15. The data processing apparatus according to claim 5, wherein the controlling module is configured to:
in the inference working mode, connect the first inputting sub-module to the first connection end side of the bidirectional data processing module to provide the inputting signal of the first inputting data of the inference computing task, and connect the first outputting sub-module to the second connection end side of the bidirectional data processing module to receive the computing result of the inference computing task and generate the first outputting data; and
in the training working mode, connect the second inputting sub-module to the second connection end side of the bidirectional data processing module to provide the inputting signal based on the second inputting data of the training computing task, and connect the second outputting sub-module to the first connection end side of the bidirectional data processing module to receive the computing result of the training computing task and generate the second outputting data.

16. The data processing apparatus according to claim 8, wherein the controlling module is configured to:
in response to the inference working mode, connect the first inputting and outputting sub-module to the first connection end side of the bidirectional data processing module to provide the inputting signal of the first inputting data based on the inference computing task, and connect the second inputting and outputting sub-module to the second connection end side of the bidirectional data processing module to receive the computing result of the inference computing task and generate the first outputting data; and
in the training working mode, connect the second inputting and outputting sub-module to the second connection end side of the bidirectional data processing module to provide the inputting signal of the second inputting data based on the training computing task, and connect the first inputting and outputting sub-module to the first connection end side of the bidirectional data processing module to receive the computing result of the training computing task and generate the second outputting data.
